(19) United States
(12) Patent Application Publication
(10) Pub. No.: US 2017/0260079 A1
(43) Pub. Date: Sep. 14, 2017

(54) PRE-COMPRESSED GLASS ARTICLE

(71) Applicant: Corning Incorporated, Corning, NY (US)

(72) Inventors: Jason Thomas Harris, Horseheads, NY (US); Guangli Hu, Berkeley Heights, NJ (US); Yousef Kayed Qaroush, Painted Post, NY (US); Irene Marjorie Slater, Lindley, NY (US); Vijay Subramanian, Painted Post, NY (US); Sam Samer Zoubi, Horseheads, NY (US)

(21) Appl. No.: 15/455,910

(22) Filed: Mar. 10, 2017

Related U.S. Application Data
(60) Provisional application No. 62/307,860, filed on Mar. 14, 2016.

(51) Int. Cl. C03B 27/012; H05K 5/00; H05K 5/03; C03C 21/00

(52) U.S. Cl. CPC C03B 27/012; C03C 21/00; H05K 5/0017; H05K 5/03

(57) ABSTRACT

Glass articles comprising an outer region extending from an outer surface of the glass article to a depth of layer and methods of making the same are described. The outer region is bounded by at least one edge of the glass article and is under an intrinsic neutral stress or an intrinsic compressive stress. A core region of the glass article is under a tensile stress. A compressive element applies an external compressive stress to the at least one edge and increases the intrinsic stress on the outer region and reduces the tensile stress in the core region of the glass article. The glass article may be a strengthened glass article such that the outer region is under compressive stress, and the external compressive stress applied by the compressive element has a magnitude such that the glass article has an overall internal stress defined by:

∫₀^{t}σdt≠0

where t is a thickness of the glass article and σ is the internal stress.

### CROSS-REFERENCE TO RELATED APPLICATIONS

This application claims the benefit of priority of U.S. Provisional Application Ser. No. 62/307,860 filed on Mar. 14, 2016, which is incorporated herein by reference, in its entirety.

### FIELD

Embodiments of the disclosure generally relate to glass articles with enhanced mechanical reliability.

### BACKGROUND

Handheld electronic devices such as mobile phones and tablets include a cover substrate, which is typically a glass substrate and is typically referred to as a cover glass. Typically, a cover glass comprises a strengthened glass substrate having a stress profile in which there is a compressive stress (CS) on the surface and tension (central tension, or CT) in the center of the glass. The failure and breakage of cover glass can be attributed to flexure failure, caused by the bend of glass when the device is subjected to the dynamic load due to impact, as well as sharp contact failure, caused by damage introduction due to sharp indentation on the glass surface when the cover glass falls on a rough surface such as asphalt, granite, etc.

Manufacturers of glass and handheld electronic device manufacturers have researched improvements to provide resistance to and/or prevent sharp contact failure. Some proposed improvements include coatings on the cover glass and bezels that prevent the cover glass from touching the ground directly when the device is dropped. However due to the constraints of aesthetic and functional requirements, it is very difficult to prevent the cover glass from completely touching the ground when the device is dropped. Also, it has been shown that hard coatings on strong ion exchanged glass, which is used to make cover glass, can deteriorate its flexural strength performance.

Glass used in other applications, such as auto-glazings, architectural glazings and appliance glass, can also experiences damage that can introduce large flaws, as deep as approximately 200 μm. For this reason, a strengthened glass substrate having a stress profile in which there is a compressive stress (CS) on the surface and tension (central tension, or CT) in the center of the glass can be used in each of these applications, and such strengthened glass can reduce damage. However, large, deep flaws can extend into the central tension region, which can cause strengthened glass failure. Thus, there is a need to provide ways to improve the reliability of glass substrates in a variety of applications.

### SUMMARY

A first embodiment of the disclosure is directed to a glass article comprising an outer region, a core region and a compressive element. The outer region extends from an outer surface to a depth of layer and is bounded by at least one edge. The outer region has an intrinsic stress that is an intrinsic neutral stress or an intrinsic compressive stress. The core region is under tensile stress. The compressive element applies an external compressive stress to the at least one edge.

In a second embodiment, the glass article of the first embodiment has a major plane, and the compressive element applies the external compressive stress in a direction substantially coplanar with the major plane.

In a third embodiment, the glass article of the first or second embodiment is a strengthened glass article such that the outer region is under compressive stress, and the external compressive stress applied by the compressive element has a magnitude such that the compressive element increases the intrinsic stress on the outer region and reduces the tensile stress in the core region of the glass article.

In a fourth embodiment, the glass article of the third embodiment has an overall internal stress less than zero.

In a fifth embodiment, the glass article of any of the first through fourth embodiments has an external compressive stress applied by the compressive element in the range of about 2 MPa to about 500 MPa.

In a sixth embodiment, the glass article of any of the first through fifth embodiments has a compressive element that extends continuously around the at least one edge.

In a seventh embodiment, the glass article of any of the first through sixth embodiments has a compressive element that applies a uniaxial external compressive stress.

In an eighth embodiment, the glass article of any of the first through sixth embodiments has a compressive element that applies a biaxial external compressive stress.

In a ninth embodiment, the glass article of any of the first through sixth and eighth embodiments has a compressive element that applies an equi-biaxial external compressive stress.

In a tenth embodiment, the glass article of any of the first through ninth embodiments further comprises an adhesive disposed between the at least one edge of the glass article and the compressive element.

In an eleventh embodiment, the glass article of any of the first through tenth embodiments is selected from the group consisting of: a handheld device display screen, an automotive glazing, an architectural glass, and an appliance glass.

In a twelfth embodiment, the glass article of any of the first through eleventh embodiments has an outer region and core region that form a strengthened glass substrate selected from the group consisting of: a laminated glass substrate, a chemically strengthened glass substrate, a thermally strengthened glass substrate. and combinations thereof

In a thirteenth embodiment, the glass article of any of the first through twelfth embodiments has a compressive element that comprises a frame that applies the external compressive stress to the glass article.

In a fourteenth embodiment, the glass article of the thirteenth embodiment has a compressive element that further comprises an adhesive in contact with the at least one edge of the glass article.

In a fifteenth embodiment, the glass article of any of the first through fourteenth embodiments has an external compressive stress applied by the compressive element that increases a stress corrosion resistance of the glass article.

In a sixteenth embodiment, a consumer electronic product is provided comprising: a housing having a front surface, a back surface and side surfaces; electrical components provided at least partially within the housing, the electrical components including at least a controller, a memory, and a display, the display being provided at or adjacent the front surface of the housing; and a cover glass disposed over the display, wherein at least one of a portion of the housing or the cover glass comprises the glass article of any of the first through fifteenth embodiments.

A seventeenth embodiment is directed to a glass article having a major plane bounded by at least one edge of the glass article. The glass article comprises an outer region, a core region, and a compressive element. The outer region extends from an outer surface of the glass article to a depth of layer. The outer region is under an intrinsic neutral stress or an intrinsic compressive stress. The core region is under a tensile stress. The compressive element is configured to apply an external compressive stress to the at least one edge of the glass article in a direction substantially coplanar with the major plane such that the glass article has an overall internal stress defined by:

∫₀^{t}σdt≠0

where t is a thickness of the glass article and σ is the internal stress.

In an eighteenth embodiment, the glass article of the seventeenth embodiment has an overall internal stress that is less than zero.

In eighteenth nineteenth embodiment, the glass article of the seventeenth or eighteenth embodiment has an external compressive stress applied by the compressive element in the range of about 2 MPa to about 500 MPa.

In a twentieth embodiment, the glass article of any of the seventeenth through nineteenth embodiments has a compressive element that extends continuously around the at least one edge of the glass article.

In a twenty-first embodiment, the glass article of any of the seventeenth through twentieth embodiments is selected from the group consisting of: a handheld device display screen, an automotive glazing, an architectural glass, and an appliance glass.

In a twenty-second embodiment, the glass article of any of the seventeenth through twenty-first embodiments has an outer region and core region that form a strengthened glass substrate selected from the group consisting of: a chemically strengthened glass substrate, a thermally strengthened glass substrate, and a chemically and thermally strengthened glass substrate.

In a twenty-third embodiment, the glass article of any of the seventeenth through twenty-second embodiments has a compressive element that exerts a compressive stress that is less than about 80% of the Critical Buckling Stress of the glass article.

In a twenty-fourth embodiment, the glass article of any of the seventeenth through twenty-third embodiments has an external compressive stress applied by the compressive element that increases a stress corrosion resistance of the glass article.

In a twenty-fifth embodiment, a consumer electronic product is provided comprising: a housing having a front surface, a back surface and side surfaces; electrical components provided at least partially within the housing, the electrical components including at least a controller, a memory, and a display, the display being provided at or adjacent the front surface of the housing; and a cover glass disposed over the display, wherein at least one of a portion of the housing or the cover glass comprises the glass article of any of the seventeenth through twenty-fourth embodiments.

A twenty-sixth embodiment is directed to a method of strengthening a glass article. The method includes applying an external compressive stress to at least one edge of the glass article with a compressive element. The glass article comprises an outer region under an intrinsic neutral stress or an intrinsic compressive stress and a core region under a tensile stress. The glass article has a major plane bounded by at least one edge of the glass article.

In a twenty-seventh embodiment, the method of the twenty-sixth embodiment wherein applying the external compressive stress comprises increasing a force applied to the at least one edge of the glass article by the compressive element.

In a twenty-eighth embodiment, the method of the twenty-sixth or twenty-seventh embodiment further comprises positioning a compressive element in contact with the at least one edge of the glass article, and applying a force substantially coplanar with the major plane to the at least one edge of the glass article with the compressive element.

In a twenty-ninth embodiment, the method of the twenty-sixth or twenty-seventh embodiment further comprises disposing an adhesive between the compressive element and the at least one edge of the glass article.

In a thirtieth embodiment, the method of any of the twenty-sixth through twenty-ninth embodiments produces a glass article selected from the group consisting of: a handheld device display screen, an automotive glazing, an architectural glass, and an appliance glass

In a thirty-first embodiment, the method of any of the twenty-sixth through thirtieth embodiments is provided wherein the compressive element comprises a frame around a periphery of the glass article.

In a thirty-second embodiment, the method of any of the twenty-sixth through thirty-first embodiments has an external compressive stress applied by the compressive element that increases a stress corrosion resistance of the glass article.

In a thirty-third embodiment, any of the twenty-sixth through thirty-second embodiments have a compressive element that exerts a compressive stress that is less than about 80% of a Critical Buckling Stress of the glass article

### BRIEF DESCRIPTION OF THE DRAWINGS

FIG. 1 illustrates a pre-compression configuration in accordance with one or more embodiments of the disclosure;

FIG. 2 illustrates a graph predicting the critical buckling stress (MPa) as a function of glass thickness (mm);

FIG. 3 shows a model schematic of a glass article for prophetic stress intensity factor calculations for a crack as a function of externally applied confinement pressure;

FIG. 4 shows a graph predicting the stress intensity factor as a function of confinement pressure for varying crack depths for the model glass article of FIG. 3;

FIG. 5 shows a perspective schematic view of a glass article in accordance with one or more embodiments of the disclosure;

FIG. 6 shows a cross-sectional schematic view of a glass article in accordance with one or more embodiments of the disclosure;

FIG. 7 shows a cross-sectional schematic view of a glass article in accordance with one or more embodiments of the disclosure;

FIG. 8 shows a perspective schematic view of a glass article in accordance with one or more embodiments of the disclosure;

FIG. 9 is a top view of a round glass article in accordance with one or more embodiments of the disclosure;

FIG. 10 is a top view of a pentagonal glass article in accordance with one or more embodiments of the disclosure;

FIG. 11 is a top view of a rectangular glass article in accordance with one or more embodiments of the disclosure;

FIG. 12 is a top view of a rectangular glass article in accordance with one or more embodiments of the disclosure;

FIG. 13 is a perspective schematic view of a curved glass article in accordance with one or more embodiments of the disclosure;

FIG. 14 is a cross-sectional schematic view of a curved glass article in accordance with one or more embodiments of the disclosure;

FIG. 15A is a plan view of an exemplary electronic device incorporating any of the glass articles disclosed herein; and

FIG. 15B is a perspective view of the exemplary electronic device of FIG. 15A.

### DETAILED DESCRIPTION

Before describing several exemplary embodiments, it is to be understood that the disclosure is not limited to the details of construction or process steps set forth in the following disclosure. The disclosure provided herein is capable of other embodiments and of being practiced or being carried out in various ways.

Embodiments of the disclosure provide a glass article which is pre-compressed uniformly in the device level in addition to the strengthening mechanism of the glass article. As used herein according to one or more embodiments, “pre-compressed” and “pre-compression” refer to an externally applied compressive stress that is applied to the at least one edge of a glass article which changes the intrinsic stress in at least one region of the glass article. In an embodiment, such a glass article has an outer region extending from an outer surface to a depth of layer, the outer region is bounded by at least one edge, the outer region is under an intrinsic stress that is a neutral stress or an intrinsic compressive stress, and the glass article has a core region under a tensile stress. Pre-compression exerts an applied compressive stress on at least one edge of the article and increases the intrinsic stress of the outer region and reduces the tensile stress in the core region of the glass article. According to one or more embodiments provided herein, a compressive element applies an external compressive stress to the glass article such that the intrinsic compressive stress of the outer region increases by at least 5% of the intrinsic compressive stress in the outer region in the absence of the applied compressive stress, such as an increase of at least 10%, 15%, 20%, 25%, 30%, 35%, 40%, 45%, 50%, 55%, 60%, 65%, 70%, 75%, 80%, 85%, 90%, or 100%. In one or more embodiments, a compressive element applies an external compressive stress to the glass article such that the applied compressive stress reduces the intrinsic tensile stress in the core region of the glass article by at least 5% of the intrinsic tensile stress in the core region in the absence of the applied compressive stress, such as a decrease of at least 10%, 15%, 20%, 25%, 30%, 35%, 40%, 45%, 50%, 55%, 60%, 65%, 70%, 75%, 80%, 85%, 90%, or 100%.

Some embodiments of the disclosure provide methods of producing a pre-compressed glass article or substrate for handheld devices, automobile glazings, architectural glazings, or glass articles for appliances. According to one or more embodiments, the stress corrosion resistance (fatigue) and damage resistance of glass articles is significantly increased, while adding minimal or no additional manufacturing cost or glass component cost. According to one or more embodiments, “handheld device” refers to a portable electronic device that has a display screen. Non-limiting examples of such handheld devices include a mobile telephone, a reading device, a music device, a viewing device and a navigation device.

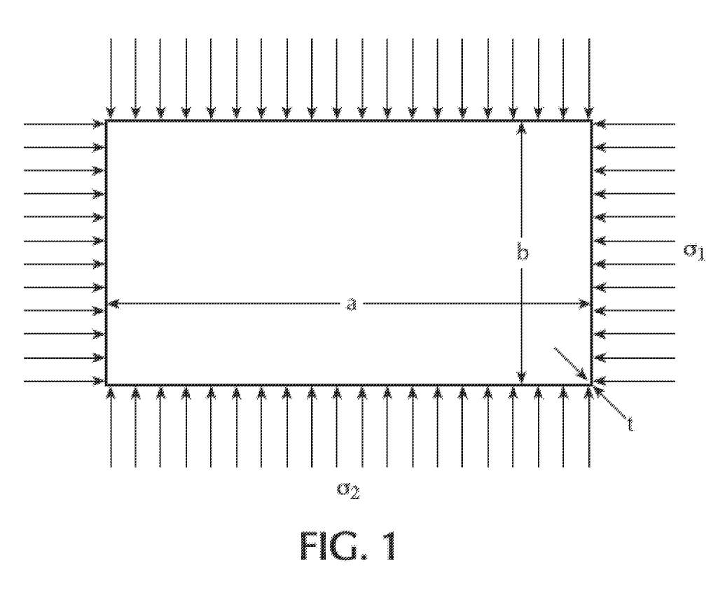

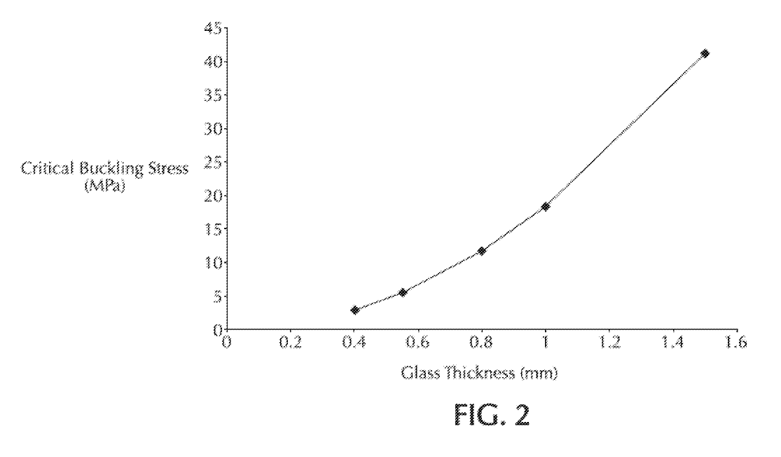

A biaxial loading scenario of a glass article according to one or more embodiments is shown in FIG. 1, taking into consideration the buckling failure mode of a thin plate under a biaxial compressive stress. Based on the Euler buckling equations adapted for a thin, simply supported plate, the Critical Buckling Stress ((σ₁)_{cr}) is given by Equation (1):

$${( {σ}_{1} )}_{cr} = \frac{D {{π}^{2} [ {( m / a )}^{2} + {( n / b )}^{2} ]}^{2}}{t [ {( m / a )}^{2} + {β ( n / b )}^{2} ]}$$

where m and n are the respective number of half-waves of buckling, t is the plate thickness, a and b are the dimensions of the plate, and β is the ratio of the stresses applied to the side of the plate (β=1 for equi-biaxial loading), and D is defined by Equation (2):

$$D = \frac{{Et}^{3}}{12 ( 1 - {v}^{2} )}$$

where E is the elastic modulus and v is the Poisson's ratio. Assuming a plate with dimensions a=70 mm and b=140 mm, having E=70 GPa, and v=0.2. The Critical Buckling Stress ((σ₁)_{cr}) given in MPa) as a function of the glass thickness (t given in mm) is shown in FIG. 2.

The Critical Buckling Stress is on the order of the stress required to completely counteract the central tension imposed by the re-equilibration of the stresses due to compressive stress. Euler equations for buckling tend to overestimate the critical load because of the assumptions of perfect geometry and loading. However, this assumes a simply supported plate. The glass article in a hand-held device may be better approximated by a cantilever supported plate, and the effective plate area can possibly be decreased, with both factors capable of substantially increasing the Critical Buckling Stress. It may be possible to provide additional fixturing to further increase the Critical Buckling Stress.

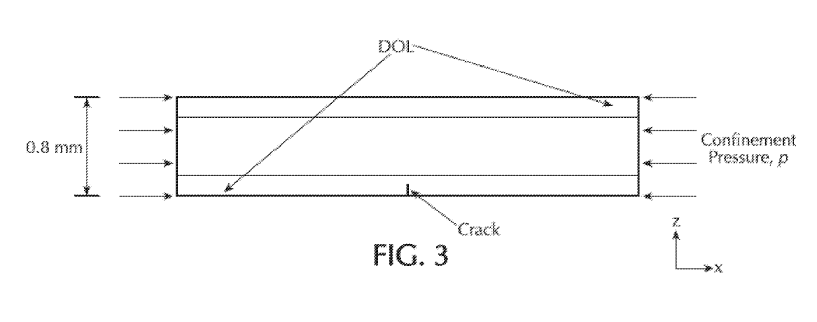

Assuming that buckling does not occur, the stress intensity factors for a given crack can be calculated as a function of pre-compression. FIG. 3 shows a model schematic of a glass article for prophetic stress intensity factor calculations for a crack as a function of externally applied compressive stress (or confinement pressure). FIG. 3 shows the schematic of a model used for calculations based on the following parameters: 0.8 mm glass thickness (t); Young's modulus (E) of 70 GPa; Poisson's ratio (v) of 0.22; Ion-exchange profile with 900 MPa of surface compression, 45 micron depth of layer (DOL), and 42.1 MPa central tension (CT). The stress states considered for these calculations were ion-exchanged residual stress along with applied compressive stress.

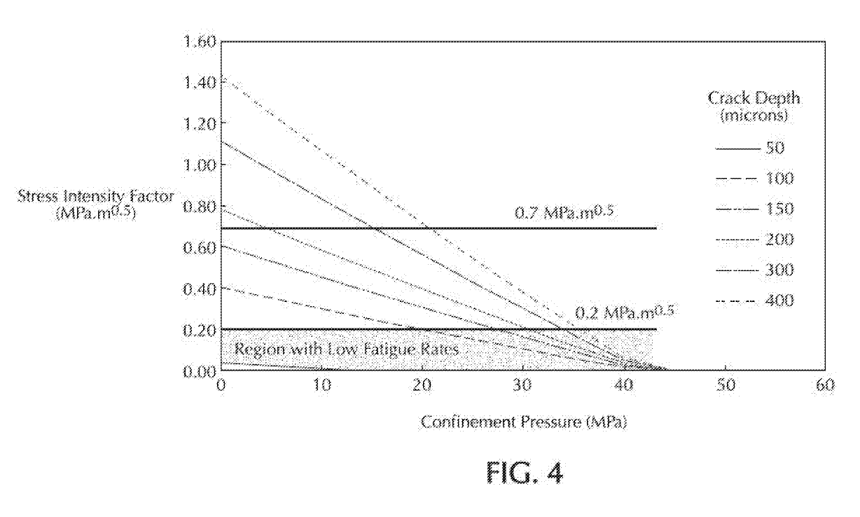

FIG. 4 shows a graph predicting the stress intensity factor as a function of applied compressive stress (or confinement pressure) for varying crack depths for the model glass article of FIG. 3. FIG. 4 shows theoretically that applied compressive stress clearly reduced the stress intensity factor for a given crack depth. When the applied compressive stress was greater than the central tension of the glass (42.1 MPa), the stress intensity factor becomes zero due to full crack closure and stress corrosion (also referred to as fatigue growth) is effectively arrested. When the applied compressive stress was less than the central tension, the stress intensity factor was lowered but is non-zero and stress corrosion continues. Without wishing to be bound by any particular theory, lowering the stress intensity factor to below 0.2 MPa·m^{0.5} may reduce stress corrosion rates significantly in glass. For cracks that are initially as deep as 100 microns, the threshold applied compressive stress that would reduce the stress intensity factor below 0.2 MPa·m^{0.5} is about 20 MPa. For shallow cracks this threshold is smaller, thereby reducing buckling tendencies as well. Ultimately, the maximum allowable applied compressive stress could be affected by buckling considerations, and an applied compressive stress that is allowable will reduce stress corrosion rates. Traditionally, strengthened glass articles have to be in force equilibrium, which can be expressed mathematically as shown in Equation (3):

$${\int }_{0}^{t} σ dt = 0$$

where t is the glass article thickness and σ is the internal stress of the glass article due to the strengthening process, e.g., chemical strengthening, thermal tempering, or lamination of materials with a CTE mismatch. With an applied compressive stress on the glass article, Equation (3) is not satisfied, as shown in Equation (4),

$${\int }_{0}^{t} {σ}_{combined} dt = {\int }_{0}^{t} ( σ + {σ}_{confinement} ) dt = {σ}_{confinement} t \neq 0$$

σ_{confinement} is the stress applied to the glass article, σ_{confinement}t is the force per unit length applied to the strengthened glass article, σ_{combined} is σ+σ_{confinement}. Given the calculation above, as shown in FIG. 2, the pre-compressed glass article can have the σ_{confinement}t ranging from 2 N/mm to 60 N/mm, or even higher, whereas for a traditional strengthened glass article σ_{confinement}t will be 0 N/mm.

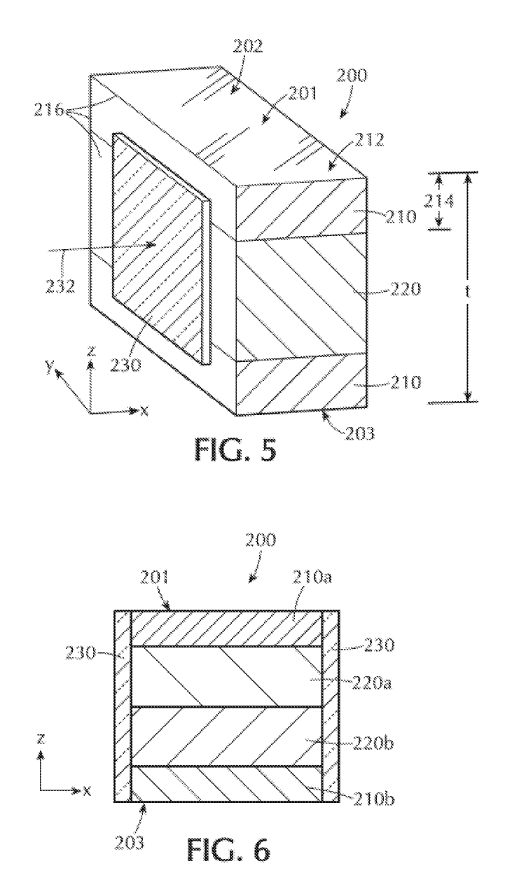

With reference to FIG. 5, one or more embodiments of the disclosure are directed to glass articles 200 comprising an outer region 210 and a core region 220. The outer region 210 extends from an outer surface 212 to a depth of layer 214. The outer region 210 is bounded by at least one edge 216. The outer region 210 is under an intrinsic stress that is a neutral stress or an intrinsic compressive stress. As used herein, “neutral stress” refers to zero stress.

A core region 220 is shown positioned between two outer regions 210. The core region 220 is under tensile stress. Those skilled in the art will understand that there can be one outer region 210 or multiple outer regions 210 surrounding multiple core regions 220. For example, some embodiments have a single outer region 210 adjacent to and in contact with a single core region 220.

Some embodiments have at least one core region 220 positioned between outer regions. FIG. 6 shows an embodiment in which two core regions 220a, 220b are in contact with each other. A first outer region 210a is adjacent to and in contact with the first core region 220a and a second outer region 210b is adjacent to and in contact with the second core region 220b. The first core region 220a and second core region 220b can have the same degree of tensile stress or different degrees of tensile stress. The first outer region 210a and the second outer region 210b can have the same degree of compressive stress or different degrees of compressive stress.

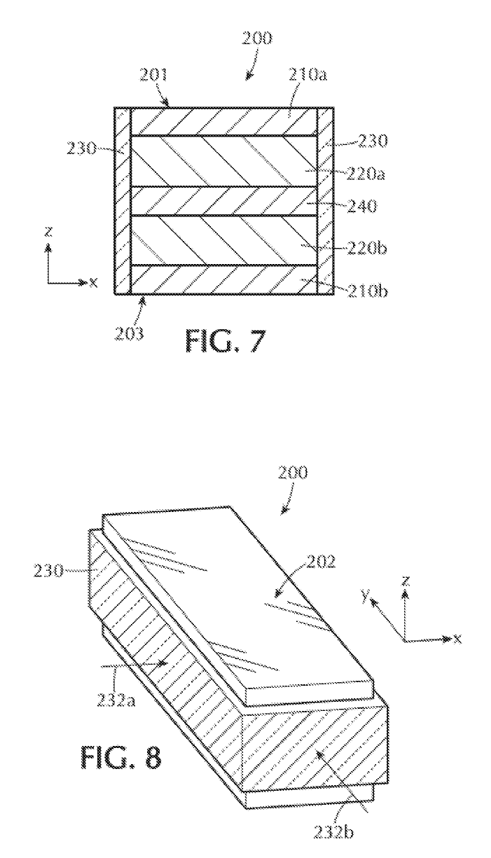

FIG. 7 shows another embodiment in which an inner region 240 is surrounded by and in contact with a first core region 220a and a second core region 220b. The first core region 220a is between and in contact with the first outer region 210a and the inner region 240. The second core region 220b is between and in contact with the second outer region 210b and the inner region 240. Each of the inner region 240, first outer region 210a and second outer region 210b can independently have the same degree of compressive stress or different degrees of compressive stress relative to any of the other of the first outer region 210a, the second outer region 210b and the inner region 240. The first core region 220a and second core region 220b can have the same degree of tensile stress or different degrees of tensile stress.

Referring back to FIG. 5, the glass article 200 has a major plane 202. The major plane 202 of the glass article 200 is defined by the primary surface of the glass article that might be contacted or touched by a user. For example, the major plane of a handheld device (e.g., a mobile phone) would be the surface that the user touches. Another example of the major plane of an automotive glass would be the surface that windshield wipers would contact or, alternatively, form the inside surface facing the interior of a vehicle. Those skilled in the art will understand that the major plane 202 of the article 200 can have a degree of curvature and does not need to be a flat surface. For example, an automotive windshield is a curved surface that has a major plane.

For descriptive purposes, FIG. 5 shows the major plane 202 as lying along the x-y plane of the illustrated Cartesian coordinate. A compressive element 230 applies an external compressive stress to the at least one edge 216 and increases the compressive stress on the outer region 210 and reduces the tensile stress in the core region 220 of the glass article 200. The compressive element 230 shown in FIG. 5 lies substantially along the x-z plane and applied compressive stress 232 is along the x-axis in a direction substantially coplanar with the major plane 202. As used in this specification and the appended claims, the term “substantially coplanar” used in this regard means that the compressive stress is within ±10° of coplanar, where a perfectly coplanar stress is defined as 0°.

The glass article 200 of various embodiments is a strengthened glass article such that the outer region 210 is under compressive stress, and the external compressive stress 232 applied by the compressive element 230 has a magnitude such that the glass article 200 has an overall internal stress defined by Equation 5:

∫₀^{t}σdt≠0

where t is a thickness of the glass article 200 and σ is the internal stress. The internal stress (σ) is a function of the measurement position through the thickness (t) of the article 200. For example, with reference to FIG. 5, the overall internal stress is measured from the top surface 201 to the bottom surface 203 through the article thickness t.

In some embodiments, the overall internal stress of the glass article 200 is greater than zero. In some embodiments, the overall internal stress of the glass article 200 is less than zero. As used herein according to one or more embodiments, “overall internal stress” refers to a sum of internal stress measurements orthogonal to the major plane. Stress profiles of glass articles can be determined using any suitable technique including, but not limited to, a refracted near-field (RNF) method or scattered light polariscope (SCALP) method. In one or more embodiments, the overall internal stress of the glass article is less than or equal to about −0.75 MPa·mm, such as less than or equal to −1 MPa·mm, −2 MPa·mm, −3 MPa·mm, −4 MPa·mm, −5 MPa·mm, −6 MPa·mm, −7 MPa·mm, −8 MPa·mm, −9 MPa·mm, −10 MPa·mm, −100 MPa·mm, −1,000 MPa·mm, −1,500 MPa·mm, or less. In one or more embodiments, the overall internal stress of the glass article is greater than or equal to about 0.75 MPa·mm, such as greater than or equal to 1 MPa·mm, 2 MPa·mm, 3 MPa·mm, 4 MPa·mm, 5 MPa·mm, 6 MPa·mm, 7 MPa·mm, 8 MPa·mm, 9 MPa·mm, 10 MPa·mm, 100 MPa·mm, 1,000 MPa·mm, 1,500 MPa·mm, or more.

In some embodiments, the residual stress due to the strengthening of the glass article as a function of the thickness of the glass article is equal to about 0, and the externally applied stress due to the compressive element is substantially constant over the thickness of the glass article. For example, the thickness of the article times the externally applied stress is in the range of about 0.75 MPa·mm to about 1,750 MPa·mm, such as in than range of about 2 MPa·mm to about 1,000 MPa·mm, about 10 MPa·mm to about 500 MPa·mm, or any sub-ranges contained therein.

In some embodiments, the thickness of the glass article is in the range of about 75 μm to about 3.5 mm, such as in the range of about 0.1 mm to about 3 mm, about 0.2 mm to about 2.5 mm, about 0.3 mm to about 1.5 mm, or any sub-ranges contained therein.

In one or more embodiments, the external compressive stress is in the range of about 2 MPa to about 500 MPa, such as in the range of about 5 MPa to about 500 MPa, about 10 MPa to about 500 MPa, about 20 MPa to about 500 MPa, about 25 MPa to about 500 MPa, about 30 MPa and about 500 MPa, 35 MPa to about 500 MPa, or any sub-ranges contained therein.

The size of the compressive element 230 can vary depending on, for example, the external compressive stress being applied. In the embodiment shown in FIG. 5, the compressive element 230 is smaller than one side of the glass article 200. In FIGS. 6 and 7, the compressive element 230 extends from the top surface 201 to the bottom surface 203 of the article 200 so that the compressive element has the same thickness as that of the article. Those skilled in the art will understand that the relative dimensions of the drawings (height, width and length) are not to scale and should not be taken as limiting the scope of the disclosure.

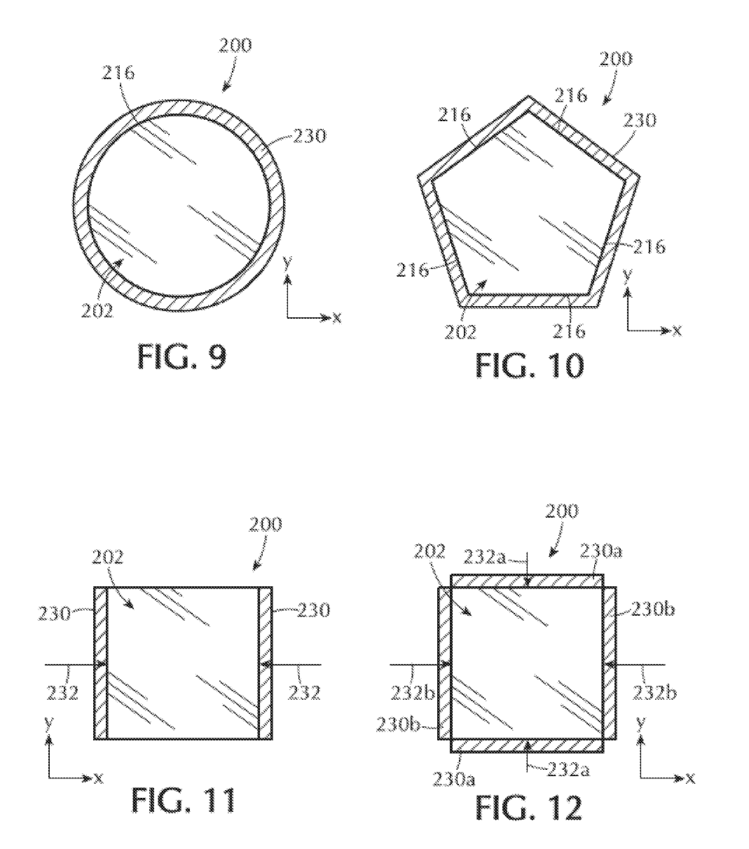

The compressive element 230 can be positioned on one or more sides of the glass article 200. In the embodiment shown in FIG. 5, the compressive element is located on one side of the glass article; however, those skilled in the art will recognize that the compressive element could also be positioned on the side of the glass article that is not visible due to the perspective view shown. In FIG. 8, for example, the compressive element 230 extends continuously around at least one edge of the glass article. FIG. 9 shows a top view of a circular or oval shaped glass article, in which there is only one edge 216. In this embodiment, the compressive element 230 extends continuously around the edge 216 of the article. FIG. 10 shows another embodiment with a generally pentagonal article having five edges 216. The compressive element 230 is shown extending continuously around all five edges 216 of this embodiment.

The compressive loading applied by the compressive element can apply uniaxial external compressive stress or biaxial external compressive stress. In FIG. 5 a uniaxial compressive stress loading is shown, and only the compressive element 230 is on the left side of article is visible. However, it will be understood, that an applied “uniaxial” compressive stress refers to a stress applied to two sides of an article in a single axis or plane, for example in the X plane of an XYZ coordinate axis. FIG. 11 shows a top view of an article 200 showing compressive elements 230 positioned on the left and right sides thereof. The compressive loading of this article is uniaxial because an applied compressive stress is applied along a single axis or plane. The applied compressive stress may be equal from both sides, or it may be unequal.

In some embodiments, the compressive element 230 applies a biaxial external compressive stress to the article 200. FIG. 12 shows a top view of a glass article 200 with four compressive elements 230. The embodiment shown has biaxial compressive stress because compressive elements 230a apply external compressive stress along the y-axis and compressive elements 230b apply external compressive stress along the x-axis. The degree of compressive stresses applied along the x-axis and y-axis by the compressive elements can be different from each other. Compressive elements 230a apply stress 232a while compressive elements 230b apply stress 232b. As shown in FIG. 12, the magnitude of the compressive stress 232a, 232b vectors are different to indicate that the degree of stress is different.

In some embodiments, the compressive elements 230 apply equi-biaxial external compressive stress. As used in this regard, the term “equi-biaxial external compressive stress” means that the compressive stress applied along two axes (e.g. the x-axis and y-axis) are substantially the same. As used in this specification and the appended claims, the term “substantially the same” used in this manner means that the compressive stresses along the x-axis and the compressive stresses along the y-axis are within ±5% of each other, such as within ±4%, ±3%, ±2%, or ±1% of each other. For example, a circular glass article 200, like that shown in FIG. 9, the compressive loading applied to the edge 216 is biaxial. In some embodiments having non-equi-biaxial stress, there may be a change in refractive index or other optical properties of the glass article.

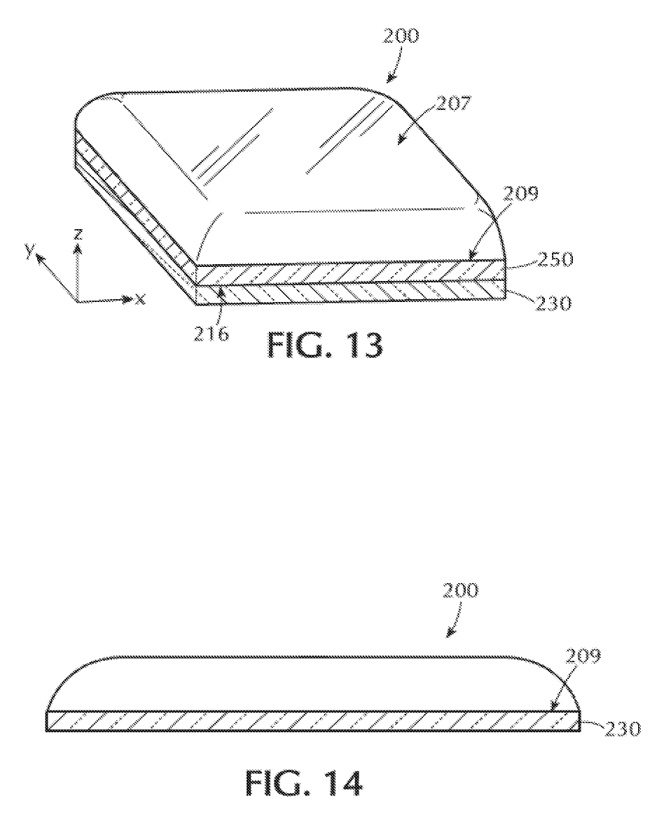

In one or more embodiments, as shown in FIG. 13, the glass article includes an adhesive 250 positioned between the at least one edge 216 of the glass article 200 and the compressive element 230. The glass article 200 shown comprises a curved surface 207 on the top and an adhesive 250 on the bottom. The compressive element 230 shown in FIG. 13 is an optional component. The adhesive 250 can be used to adhere the compressive element 230 to the glass article or can act as the compressive element in addition to allowing the glass article to be adhered to another surface (not shown).

The glass article can be any suitable glass article or glass component of a larger article. For example, the glass article can be a component of a handheld device including, but not limited to a cover glass for a display screen.

In some embodiments, the glass article is an automotive glazing such as a front or back windshield or side windows for a vehicle. In one or more embodiments, the glass article is an architectural glass (e.g., a glass panel used in a building) or an appliance glass (e.g., a glass component for an oven door).

Some aspects of the disclosure are directed to methods of strengthening a glass article. An external compressive stress can be applied to at least one edge of the glass article using a compressive element. The glass article may comprise an outer region under an intrinsic stress that is an intrinsic neutral stress or an intrinsic compressive stress and a core region under tensile stress and the glass article has a major plane bounded by the at least one edge.

Referring again to the embodiment shown in FIG. 8, in some embodiments, the compressive element 230 comprises a frame that applies the external compressive stress to a periphery of the glass article. The frame-like compressive element 230 can be any suitable shape depending on, for example, the shape of the glass article 200. FIG. 8 shows a rectangular frame-like compressive element while FIG. 9 shows a circular or ovular frame-like compressive element. The compressive element 230 in the embodiment shown in FIG. 8 does not extend to the top surface or bottom surface of the glass article. This is merely representative of one possible configuration and those skilled in the art will understand that the size of the compressive element 230 can be different. The frame-like compressive element can apply pressure to the glass article by any suitable technique. For example, the compressive element 230 may be heated to expand the shape of the element prior to placement about the edge of the glass article. Upon cooling, the compressive element 230 may shrink to apply external compressive stress to the glass article. In alternative embodiments, the frame-like compressive element 230 can apply pressure to the glass article by mechanical force. For example, the frame-like compressive element 230 can include detents that allow a user to increase the compressive force on at least one edge of the glass article, or the frame could include a threaded fastener, or the frame could be made such that the frame applies a spring force to at least one edge of the glass article.

In some embodiments, the external compressive stress applied by the compressive element is designed or configured to mitigate buckling of the glass article. For example, the external compressive stress may be designed taking into account the buckling equation described above (Equation 1), and other design features which may mitigate the risk of buckling failure. In one or more embodiments, the compressive element 230 exerts a compressive stress that is less than about 80% of the Critical Buckling Stress of the glass article. In various embodiments, the compressive element 230 exerts a compressive stress that is less than about 70% of the Critical Buckling Stress of the glass article, such as less than about 60% or less than about 50% of the Critical Buckling Stress of the glass article.

In some embodiments, a compressive element is positioned in contact with the at least one edge of the glass article and the compressive element applies force in a direction substantially coplanar with the major plane to the at least one edge of the glass article. In some embodiments, an adhesive is used to connect the compressive element to the at least one edge of the glass article.

Referring to FIG. 14, some embodiments comprise applying a compressive element 230 to apply stress across the back surface 209 of the article 200. The compressive loading is applied to the back surface 209 of the article instead of the edges of the article. If one side of the article does not need to be transparent, the compressive element 230 could be an opaque or semi-transparent epoxy which could shrink when cured. The shrinking epoxy could apply pressure to the article when cured.

In some embodiments, the shrinking epoxy results in bending of the article. The article may be formed pre-bent so that upon shrinkage, the article is flattened. In some embodiments, a secondary constraining component is positioned adjacent the article so that it remains substantially flat even after shrinkage.

The glass articles used herein can be amorphous articles or crystalline articles. Amorphous articles according to one or more embodiments can include glasses selected from soda lime glass, alkali aluminosilicate glass, alkali containing borosilicate glass, and alkali aluminoborosilicate glass. Crystalline articles according to one or more embodiments may include glass ceramic materials. In one or more embodiments, when chemically strengthened the glass articles may have a compressive stress (CS) layer with a CS extending within the chemically strengthened glass from a surface of the chemically strengthened glass to a compressive stress depth of layer (DOL) of at least 10 μm to several tens of microns deep. In one or more embodiments, the glass article may include a thermally strengthened glass article, a chemically strengthened glass article, or a combination of a thermally strengthened and chemically strengthened glass article. In one or more embodiments, the glass article may include a non-strengthened glass, for example, Eagle XG®, available from Corning Incorporated.

As used herein, “thermally strengthened” refers to articles that are heat treated to improve the strength of the article, and “thermally strengthened” includes tempered articles and heat-strengthened articles, for example tempered glass and heat-strengthened glass. Tempered glass is produced through an accelerated cooling process, which creates higher surface compression and/or edge compression in the glass. Factors that impact the degree of surface compression include the air-quench temperature, volume, and other variables that are selected to create a surface compression of at least 10,000 pounds per square inch (psi). Tempered glass is typically four to five times stronger than annealed or untreated glass. Heat-strengthened glass is produced by a slower cooling than tempered glass, which results in a lower compression strength at the surface and heat-strengthened glass is approximately twice as strong as annealed, or untreated, glass.

In chemically strengthened glass articles, the replacement of smaller ions by larger ions at a temperature below that at which the glass network can relax produces a distribution of ions in the glass and a resulting stress profile. The larger volume of the incoming ion produces a compressive stress (CS) on the surface and tension (central tension, or CT) in the center of the glass. The compressive stress is related to the central tension by the following approximate relationship given in Equation (6):

$$CT ≅ \frac{CS \times DOL}{thickness - 2 \times DOL}$$

where thickness is the total thickness of the strengthened glass article and compressive depth of layer (DOL) is the depth of ion exchange. Depth of ion exchange may be described as the depth within the strengthened glass or glass ceramic article (i.e., the distance from a surface of the glass article to an interior region of the glass or glass ceramic article), to which ion exchange facilitated by the ion exchange process extends. Unless otherwise specified, central tension (CT) and compressive stress (CS) are expressed herein in megaPascals (MPa), whereas thickness and depth of layer (DOL) are expressed in millimeters or microns.

Compressive stress (including surface CS) and depth of layer (DOL) are measured by surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety.

For strengthened glass articles in which the CS layers extend to deeper depths within the glass article, the FSM technique may suffer from contrast issues which affect the observed DOL value. At deeper DOL values, there may be inadequate contrast between the transverse electronic (TE) and transverse magnetic (TM) spectra, thus making the calculation of the difference between TE and TM spectra—and determining the DOL—more difficult. Moreover, the FSM technique is incapable of determining the stress profile (i.e., the variation of CS as a function of depth within the glass-based article). In addition, the FSM technique is incapable of determining the DOL resulting from the ion exchange of certain elements such as, for example, sodium for lithium.

The techniques described below have been developed to more accurately determine a depth of compression (DOC) defined as the depth at which the stress within the glass substrate changes from compressive to tensile stress, and stress profiles for strengthened glass-based articles.

In U.S. Pat. No. 9,140,543, entitled “Systems And Methods for Measuring the Stress Profile of Ion-Exchanged Glass (hereinafter referred to as “Roussev I”),” filed by Rostislav V. Roussev et al. on May 3, 2012, and claiming priority to U.S. Provisional Patent Application No. 61/489,800, having the same title and filed on May 25, 2011, two methods for extracting detailed and precise stress profiles (stress as a function of depth) of tempered or chemically strengthened glass are disclosed. The spectra of bound optical modes for TM and TE polarization are collected via prism coupling techniques, and used in their entirety to obtain detailed and precise TM and TE refractive index profiles n_{TM}(z) and n_{TE}(z). The contents of the above applications are incorporated herein by reference in their entirety.

In one embodiment, the detailed refractive index profiles are obtained from the mode spectra by using the Inverse Wentzel-Kramers-Brillouin (IWKB) method.

In another embodiment, the detailed refractive index profiles are obtained by fitting the measured mode spectra to numerically calculated spectra of pre-defined functional forms that describe the shapes of the refractive index profiles and obtaining the parameters of the functional forms from the best fit. The detailed stress profile S(z) is calculated from the difference of the recovered TM and TE refractive index profiles by using a known value of the stress-optic coefficient (SOC) as defined in Equation (7):

S(z)=[n_{TM}(z)−n_{TE}(z)]/SOC

Due to the small value of the SOC, the birefringence n_{TM}(z)−n_{TE}(z) at any depth z is a small fraction (typically on the order of 1%) of either of the refractive indices n_{TM}(z) and n_{TE}(z). Obtaining stress profiles that are not significantly distorted due to noise in the measured mode spectra requires determination of the mode effective refractive indices with precision on the order of 0.00001 refractive index units (RIU). The methods disclosed in Roussev I further include techniques applied to the raw data to ensure such high precision for the measured mode refractive indices, despite noise and/or poor contrast in the collected TE and TM mode spectra or images of the mode spectra. Such techniques include noise-averaging, filtering, and curve fitting to find the positions of the extremes corresponding to the modes with sub-pixel resolution.

Similarly, U.S. Pat. No. 8,957,374, entitled “Systems and Methods for Measuring Birefringence in Glass and Glass-Ceramics (hereinafter “Roussev II”),” filed by Rostislav V. Roussev et al. on Sep. 23, 2013, and claiming priority to U.S. Provisional Application Ser. No. 61/706,891, having the same title and filed on Sep. 28, 2012, discloses apparatus and methods for optically measuring birefringence on the surface of glass and glass ceramics, including opaque glass and glass ceramics. Unlike Roussev I, in which discrete spectra of modes are identified, the methods disclosed in Roussev II rely on careful analysis of the angular intensity distribution for TM and TE light reflected by a prism-sample interface in a prism-coupling configuration of measurements. The contents of the above applications are incorporated herein by reference in their entirety.

Hence, correct distribution of the reflected optical intensity vs. angle is much more important than in traditional prism-coupling stress-measurements, where only the locations of the discrete modes are sought. To this end, the methods disclosed in Roussev 1 and Roussev II comprise techniques for normalizing the intensity spectra, including normalizing to a reference image or signal, correction for nonlinearity of the detector, averaging multiple images to reduce image noise and speckle, and application of digital filtering to further smoothen the intensity angular spectra. In addition, one method includes formation of a contrast signal, which is additionally normalized to correct for fundamental differences in shape between TM and TE signals. The aforementioned method relies on achieving two signals that are nearly identical and determining their mutual displacement with sub-pixel resolution by comparing portions of the signals containing the steepest regions. The birefringence is proportional to the mutual displacement, with a coefficient determined by the apparatus design, including prism geometry and refractive index, focal length of the lens, and pixel spacing on the sensor. The stress is determined by multiplying the measured birefringence by a known stress-optic coefficient.

In another disclosed method, derivatives of the TM and TE signals are determined after application of some combination of the aforementioned signal conditioning techniques. The locations of the maximum derivatives of the TM and TE signals are obtained with sub-pixel resolution, and the birefringence is proportional to the spacing of the above two maxima, with a coefficient determined as before by the apparatus parameters.

Associated with the requirement for correct intensity extraction, the apparatus comprises several enhancements, such as using a light-scattering surface (static diffuser) in close proximity to or on the prism entrance surface to improve the angular uniformity of illumination, a moving diffuser for speckle reduction when the light source is coherent or partially coherent, and light-absorbing coatings on portions of the input and output facets of the prism and on the side facets of the prism, to reduce parasitic background which tends to distort the intensity signal. In addition, the apparatus may include an infrared light source to enable measurement of opaque materials.

Furthermore, Roussev II discloses a range of wavelengths and attenuation coefficients of the studied sample, where measurements are enabled by the described methods and apparatus enhancements. The range is defined by αₛλ<250πσₛ, where αₛ is the optical attenuation coefficient at measurement wavelength λ, and σₛ is the expected value of the stress to be measured with typically required precision for practical applications. This wide range allows measurements of practical importance to be obtained at wavelengths where the large optical attenuation renders previously existing measurement methods inapplicable. For example, Roussev II discloses successful measurements of stress-induced birefringence of opaque white glass-ceramic at a wavelength of 1,550 nm, where the attenuation is greater than about 30 dB/mm.

While it is noted above that there are some issues with the FSM technique at deeper DOL values, FSM is still a beneficial conventional technique which may utilized with the understanding that an error range of up to ±20% is possible at deeper DOL values. DOL as used herein refers to depths of the compressive stress layer values computed using the FSM technique, whereas DOC refer to depths of the compressive stress layer determined by the methods described in Roussev I & II.

The Young's modulus value recited in this disclosure refers to a value as measured by a resonant ultrasonic spectroscopy technique of the general type set forth in ASTM E2001-13, titled “Standard Guide for Resonant Ultrasound Spectroscopy for Defect Detection in Both Metallic and Non-metallic Parts.” The Poisson's ratio value recited in this disclosure refers to a value as measured by a resonant ultrasonic spectroscopy technique of the general type set forth in ASTM E2001-13, titled “Standard Guide for Resonant Ultrasound Spectroscopy for Defect Detection in Both Metallic and Non-metallic Parts.”

The materials for the glass articles may be varied. In exemplary embodiments, the glass articles may include glass or glass-ceramic. The glass may be soda lime glass, alkali aluminosilicate glass, alkali containing borosilicate glass, and/or alkali aluminoborosilicate glass. The glass-ceramic may include Li₂O—Al₂O₃—SiO₂ system (LAS-System) glass ceramics, MgO—Al₂O₃—SiO₂ System (MAS-System) glass ceramics, and/or glass ceramics including at least one crystalline phase selected from mullite, spinel, α-quartz, β-quartz solid solution, petalite, lithium disilicate, β-spodumene, nepheline, and alumina. In some embodiments, the compositions used for a glass article may be batched with 0-2 mol % of at least one fining agent selected from a group that includes Na₂SO₄, NaCl, NaF, NaBr, K₂SO₄, KCl, KF, KBr, and SnO₂.

Glass articles may be provided using a variety of different processes. For example, exemplary glass article forming methods include float glass processes and down-draw processes such as fusion draw and slot draw. A glass article prepared by a float glass process may be characterized by smooth surfaces and uniform thickness, and is made by floating molten glass on a bed of molten metal, typically tin. In an exemplary process, molten glass that is fed onto the surface of the molten tin bed forms a floating glass ribbon. As the glass ribbon flows along the tin bath, the temperature is gradually decreased until the glass ribbon solidifies into a solid glass article that can be lifted from the tin onto rollers. Once off the bath, the glass article can be cooled further and annealed to reduce internal stress.

Down-draw processes produce glass articles having a uniform thickness that possess relatively pristine surfaces. Because the average flexural strength of the glass article is controlled by the amount and size of surface flaws, a pristine surface that has had minimal contact has a higher initial strength. When this high strength glass article is then further strengthened (e.g., chemically), the resultant strength can be higher than that of a glass article with a surface that has been lapped and polished. Down-drawn glass articles may be drawn to a thickness of less than about 2 mm. In addition, down drawn glass articles have a very flat, smooth surface that can be used in its final application without costly grinding and polishing.

The fusion draw process, for example, uses a drawing tank that has a channel for accepting molten glass raw material. The channel has weirs that are open at the top along the length of the channel on both sides of the channel. When the channel fills with molten material, the molten glass overflows the weirs. Due to gravity, the molten glass flows down the outside surfaces of the drawing tank as two flowing glass films. These outside surfaces of the drawing tank extend down and inwardly so that they join at an edge below the drawing tank. The two flowing glass films join at this edge to fuse and form a single flowing glass article. The fusion draw method offers the advantage that, because the two glass films flowing over the channel fuse together, neither of the outside surfaces of the resulting glass article comes in contact with any part of the apparatus. Thus, the surface properties of the fusion drawn glass article are not affected by such contact.

The slot draw process is distinct from the fusion draw method. In slot draw processes, the molten raw material glass is provided to a drawing tank. The bottom of the drawing tank has an open slot with a nozzle that extends the length of the slot. The molten glass flows through the slot and nozzle and is drawn downward as a continuous article and into an annealing region.

Examples of glasses that may be used to make the glass articles described herein include alkali aluminosilicate glass compositions or alkali aluminoborosilicate glass compositions, though other glass compositions are contemplated. Such glass compositions may be characterized as ion exchangeable. As used herein, “ion exchangeable” means that a substrate comprising the composition is capable of exchanging cations located at or near the surface of the substrate with cations of the same valence that are either larger or smaller in size. One example glass composition comprises SiO₂, B₂O₃ and Na₂O, where (SiO₂+B₂O₃)≧66 mol %, and Na₂O≧9 mol %. Suitable glass compositions, in some embodiments, further comprise at least one of K₂O, MgO, and CaO. In a particular embodiment, the glass compositions used in the substrate can comprise 61-75 mol % SiO₂; 7-15 mol % Al₂O₃; 0-12 mol % B₂O₃; 9-21 mol % Na₂O; 0-4 mol % K₂O; 0-7 mol % MgO; and 0-3 mol % CaO.

A further example glass composition suitable for the glass articles comprises: 60-70 mol % SiO₂; 6-14 mol % Al₂O₃; 0-15 mol % B₂O₃; 0-15 mol % Li₂O; 0-20 mol % Na₂O; 0-10 mol % K₂O; 0-8 mol % MgO; 0-10 mol % CaO; 0-5 mol % ZrO₂; 0-1 mol % SnO₂; 0-1 mol % CeO₂; less than 50 ppm As₂O₃; and less than 50 ppm Sb₂O₃; where 12 mol % (Li₂O+Na₂O+K₂O)≦20 mol % and 0 mol %≦(MgO+CaO)≦10 mol %.

A still further example glass composition suitable for the glass articles comprises: 63.5-66.5 mol % SiO₂; 8-12 mol % Al₂O₃; 0-3 mol % B₂O₃; 0-5 mol % Li₂O; 8-18 mol % Na₂O; 0-5 mol % K₂O; 1-7 mol % MgO; 0-2.5 mol % CaO; 0-3 mol % ZrO₂; 0.05-0.25 mol % SnO₂; 0.05-0.5 mol % CeO₂; less than 50 ppm As₂O₃; and less than 50 ppm Sb₂O₃; where 14 mol % (Li₂O+Na₂O+K₂O)≦18 mol %, and 2 mol % (MgO+CaO)≦7 mol %.

In a particular embodiment, an alkali aluminosilicate glass composition suitable for the glass articles comprises alumina, at least one alkali metal and, in some embodiments, greater than 50 mol % SiO₂, in other embodiments at least 58 mol % SiO₂, and in still other embodiments at least 60 mol % SiO₂, wherein the ratio ((Al₂O₃+B₂O₃)/Σ modifiers)>1, where in the ratio the components are expressed in mol % and the modifiers are alkali metal oxides. This glass composition, in particular embodiments, comprises: 58-72 mol % SiO₂; 9-17 mol % Al₂O₃; 2-12 mol % B₂O₃; 8-16 mol % Na₂O; and 0-4 mol % K₂O, wherein the ratio((Al₂O₃+B₂O₃)/Σ modifiers)>1.

In still another embodiment, the glass article may include an alkali aluminosilicate glass composition comprising: 64-68 mol % SiO₂; 12-16 mol % Na₂O; 8-12 mol % Al₂O₃; 0-3 mol % B₂O₃; 2-5 mol % K₂O; 4-6 mol % MgO; and 0-5 mol % CaO, wherein: 66 mol %≦SiO₂+B₂O₃+CaO≦69 mol %; Na₂O+K₂O+B₂O₃+MgO+CaO+SrO>10 mol %; 5 mol %≦MgO+CaO+SrO≦8 mol %; (Na₂O+B₂O₃)—Al₂O₃≦2 mol %; 2 mol %≦Na₂O-Al₂O₃≦6 mol %; and 4 mol %≦(Na₂O+K₂O)—Al₂O₃≦10 mol %.

In an alternative embodiment, the glass article may comprise an alkali aluminosilicate glass composition comprising: 2 mol % or more of at least one of Al₂O₃ and ZrO₂, or 4 mol % or more of at least one of Al₂O₃ and ZrO₂.

Once formed, a glass article may be strengthened to form a strengthened glass article. It should be noted that glass articles including glass ceramic materials may also be strengthened to form strengthened glass articles.

Another aspect of the disclosure pertains to a method of strengthening a glass article, which includes applying an external compressive stress to at least one edge of the glass article using a compressive element. The glass article includes an outer region under an intrinsic neutral stress or an intrinsic compressive stress and a core region under tensile stress, the glass article having a major plane bounded by the at least one edge. In one or more embodiments, applying the external compressive stress comprises increasing a force applied to the at least one edge of the glass article by the compressive element. In one or more embodiments, the method includes positioning a compressive element in contact with the at least one edge of the glass article and using the compressive element to apply force substantially coplanar with the major plane to the at least one edge of the glass article. According to one or more embodiments, the method includes using an adhesive to connect the compressive element to the at least one edge of the glass article.

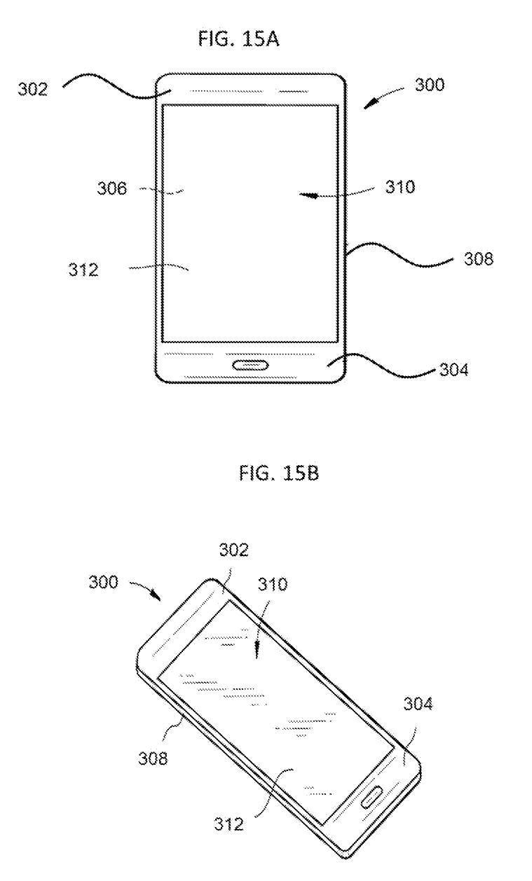

The glass articles disclosed herein may be incorporated into another article such as an article with a display (or display articles) (e.g., consumer electronics, including mobile phones, tablets, computers, navigation systems, and the like), architectural articles, transportation articles (e.g., automobiles, trains, aircraft, sea craft, etc.), appliance articles, or any article that requires some transparency, scratch-resistance, abrasion resistance or a combination thereof. An exemplary article incorporating any of the strengthened articles disclosed herein is shown in FIGS. 15A and 15B. Specifically, FIGS. 15A and 15B show a consumer electronic device 300 including a housing 302 having front 304, back 306, and side surfaces 308; electrical components (not shown) that are at least partially inside or entirely within the housing and including at least a controller, a memory, and a display 310 at or adjacent to the front surface of the housing; and a cover substrate 312 at or over the front surface of the housing such that it is over the display. In some embodiments, the cover substrate 312 or the housing 302 may include any of the glass articles disclosed herein.

While the foregoing is directed to various embodiments, other and further embodiments of the disclosure may be devised without departing from the basic scope thereof, and the scope thereof is determined by the claims that follow.

What is claimed is:

1. A glass article comprising:
an outer region extending from an outer surface of the glass article to a depth of layer, wherein the outer region is bounded by at least one edge of the glass article, and the outer region has an intrinsic stress that is an intrinsic neutral stress or an intrinsic compressive stress;
a core region under a tensile stress; and
a compressive element which applies an external compressive stress to the at least one edge.

2. The glass article of claim 1, wherein the glass article has a major plane, and the compressive element applies the external compressive stress in a direction substantially coplanar with the major plane.

3. The glass article of claim 1, wherein the glass article is a strengthened glass article such that the outer region has an intrinsic compressive stress, and the external compressive stress applied by the compressive element increases the compressive stress of the outer region and reduces the tensile stress of the core region of the glass article.

4. The glass article of claim 3, wherein the overall internal stress of the glass article is less than zero.

5. The glass article of claim 1, wherein the external compressive stress applied by the compressive element is in the range of about 2 MPa to about 500 MPa.

6. The glass article of claim 1, wherein the compressive element extends continuously around the at least one edge.

7. The glass article of claim 1, wherein the compressive element applies a uniaxial external compressive stress.

8. The glass article of claim 1, wherein the compressive element applies a biaxial external compressive stress.

9. The glass article of claim 8, wherein the compressive element applies an equi-biaxial external compressive stress.

10. The glass article of claim 1, further comprising an adhesive disposed between the at least one edge of the glass article and the compressive element.

11. The glass article of claim 1, wherein the glass article is selected from the group consisting of: a handheld device display screen, an automotive glazing, an architectural glass, and an appliance glass.

12. The glass article of claim 1, wherein the outer region and the core region form a strengthened glass selected from the group consisting of: a laminated glass substrate, a chemically strengthened glass substrate, a thermally strengthened glass substrate, and combinations thereof.

13. The glass article of claim 1, wherein the compressive element comprises a frame that applies the external compressive stress to the glass article.

14. The glass article of claim 13, wherein the compressive element further comprises an adhesive in contact with the at least one edge of the glass article.

15. The glass article of claim 1, wherein the external compressive stress applied by the compressive element increases a stress corrosion resistance of the glass article.

16. A consumer electronic product, comprising:
a housing having a front surface, a back surface and side surfaces;
electrical components provided at least partially within the housing, the electrical components including at least a controller, a memory, and a display, the display being provided at or adjacent the front surface of the housing; and
a cover glass disposed over the display,
wherein at least one of a portion of the housing or the cover glass comprises the glass article of claim 1.

17. A glass article having a major plane bounded by at least one edge, the glass article comprising:
an outer region extending from an outer surface of the glass article to a depth of layer, wherein the outer region is under an intrinsic stress that is an intrinsic neutral stress or an intrinsic compressive stress;
a core region under a tensile stress; and
a compressive element configured to apply an external compressive stress to the at least one edge in a direction substantially coplanar with the major plane, such that the glass article has an overall internal stress defined by:
∫₀^{t}σdt≠0
where t is a thickness of the glass article and σ is the internal stress.

18. The glass article of claim 17, wherein the overall internal stress of the glass article is less than zero.

19. The glass article of claim 17, wherein the external compressive stress applied by the compressive element is in the range of about 2 MPa to about 500 MPa.

20. The glass article of claim 17, wherein the compressive element extends continuously around the at least one edge.

21. The glass article of claim 17, wherein the glass article is selected from the group consisting of: a handheld device display screen, an automotive glazing, an architectural glass, and an appliance glass.

22. The glass article of claim 17, wherein the outer region and core region form a strengthened glass selected from the group consisting of a chemically strengthened glass substrate, a thermally strengthened glass substrate and a chemically and thermally strengthened glass substrate.

23. The glass article of claim 17, wherein the compressive element exerts a compressive stress that is less than about 80% of a Critical Buckling Stress of the glass article.

24. The glass article of claim 17, wherein the external compressive stress applied by the compressive element increases a stress corrosion resistance of the glass article.

25. A consumer electronic product, comprising:
a housing having a front surface, a back surface and side surfaces;
electrical components provided at least partially within the housing, the electrical components including at least a controller, a memory, and a display, the display being provided at or adjacent the front surface of the housing; and
a cover glass disposed over the display,
wherein at least one of a portion of the housing or the cover glass comprises the glass article of claim 17.

26. A method of strengthening a glass article, comprising:
applying an external compressive stress to at least one edge of the glass article using a compressive element,
wherein the glass article comprises an outer region under an intrinsic neutral stress or an intrinsic compressive stress, a core region under a tensile stress, and a major plane bounded by the at least one edge of the glass article.

27. The method of claim 26, wherein applying the external compressive stress comprises increasing a force applied to the at least one edge of the glass article by the compressive element.

28. The method of claim 26, further comprising:
disposing the compressive element in contact with the at least one edge of the glass article, and
applying a force substantially coplanar with the major plane to the at least one edge of the glass article with the compressive element.

29. The method of claim 26, further comprising disposing an adhesive between the compressive element and the at least one edge of the glass article.

30. The method of claim 26, wherein the glass article is selected from the group consisting of: a handheld device display screen, an automotive glazing, an architectural glass, and an appliance glass

31. The method of claim 26, wherein the compressive element comprises a frame around a periphery of the glass article.

32. The method of claim 26, wherein the external compressive stress applied by the compressive element increases a stress corrosion resistance of the glass article.

33. The method of claim 26, wherein the compressive element exerts a compressive stress on the at least one edge of the glass article that is less than about 80% of a Critical Buckling Stress of the glass article.
